(19) United States
(12) Patent Application Publication
(10) Pub. No.: US 2009/0117732 A1
(43) Pub. Date: May 7, 2009

(54) METHOD OF FABRICATING SEMICONDCUTOR DEVICE

(76) Inventor: Jong-Hun Shin, Siheung-si (KR)

Correspondence Address: SHERR & VAUGHN, PLLC, 620 HERNDON PARKWAY, SUITE 200, HERNDON, VA, 20170, US

(21) Appl. No.: 12/253,251

(22) Filed: Oct. 17, 2008

(30) Foreign Application Priority Data
Nov. 5, 2007 (KR) 10-2007-0112123

(51) Int. Cl. H01L 21/768

(52) U.S. Cl. 438/653; 257/E21.584

(57) ABSTRACT

A method of fabricating a semiconductor device that may include forming an insulating interlayer on and/or over a semiconductor substrate, and then forming a damascene structure by patterning the insulating interlayer, and then forming a metal layer on and/or over the insulating interlayer and filling the damascene structure, and then forming a metal line by planarizing the metal layer until an upper surface of the insulating interlayer is exposed, and then forming pores in the insulating interlayer by performing thermal treatment of the planarized structure.

The present application claims priority under 35 U.S.C. §119 to Korean Patent Application No. 10-2007-0112123 (filed on Nov. 5, 2007), which is hereby incorporated by reference in its entirety.

### BACKGROUND

Generally, in order to realize high speed and high integration of a semiconductor device, the width of metal line gets further reduced. For this, a device application technology is required. For instance, a film having a low dielectric constant (low-k) is used as an insulating layer instead of silicon oxide (SiO₂) while copper (Cu) is used as a line instead of aluminum (Al). A semiconductor fabricating process can be divided into a substrate process (FEOL: front end of the line) for forming a transistor on and/or over a silicon substrate and a line process (BEOL: back end of line). The line process is the technology for implementing paths of power supply and signal transfer on and/or over the silicon to configure a circuit by connecting individual transistors together in a semiconductor integrated circuit. As capacitance between metal lines arranged closely by an ultra-microscopic multi-layer line process and resistance of a ultra-microscopic metal line increase, a resistance-capacitance (RC) delay effect considerably affects to reduce an operational speed of a semiconductor device.

Dielectric constants (k) of various insulating layers currently used in general range from 3.5 to 5.4. Moreover, an insulating layer having a dielectric constant equal to or less than 2.7 is called a low-k insulating layer. In particular, an insulating layer having a k-value equal to or less than 3 is required for a roadmap under 90 nm. Only if an insulating layer has a k-value equal to or less than 2.0 under 65 nm, RC delay is prevented to operate a semiconductor device. Hence, an insulating layer having a k-value equal to or less than 3.9 needs to be formed. Even if an insulating layer having an ultra low-k is formed, mechanical strength should be secured in such a post process as chemical mechanical polishing (CMP).

In a method of fabricating a semiconductor device, an insulating layer is deposited, a via-hole and trench are formed by patterning, the via-hole and trench are filled up with a barrier layer and a metal such as copper (Cu), and CMP is then performed. Since an insulating layer having k in a range between approximately 2.8 to 3.0 is almost free from pores, it is able to prevent a problem attributed to mechanical strength in performing CMP. Yet, if pores are formed in an insulating layer by annealing to lower the k-value into 3.0 or below, the mechanical strength of the insulating layer is lowered due to the pores to become vulnerable to a pressure applied by CMP. Hence, a semiconductor device runs into various problems.

### SUMMARY

Embodiments relate to a semiconductor device and a method of fabricating a semiconductor device for forming a metal line using a damascene process that maximizes the mechanical strength of an insulating layer by forming a plurality of pores therein.

Embodiments relate to a method of fabricating a semiconductor device by which an insulating layer having an ultra low-k can be formed without weakening the mechanical strength of the insulating layer for a post process such as a CMP process.

Embodiments relate to a method of fabricating a semiconductor device that may include at least one of the following steps: forming an insulating interlayer on and/or over a semiconductor substrate, and then forming a via-hole and a trench by patterning the insulating interlayer, and then forming a metal layer on and/or over the insulating interlayer including filling the via-hole and the trench, and then planarizing the metal layer until an upper surface of the insulating interlayer is exposed, and then forming pores within the insulating interlayer by performing thermal treatment of the planarized structure.

Embodiments relate to a method of fabricating a semiconductor device that may include at least one of the following steps: forming an insulating interlayer on and/or over a semiconductor substrate, and then forming at least one of a via-hole and a trench by patterning the insulating interlayer, and then forming a metal layer on and/or over the insulating interlayer including filling the at least one of via-hole and the trench, and then planarizing the metal layer until an upper surface of the insulating interlayer is exposed, and then forming a plurality of pores within the insulating interlayer by performing thermal treatment of the planarized structure.

Embodiments relate to a method of fabricating a semiconductor device that may include at least one of the following steps: forming an insulating interlayer over a semiconductor substrate; and then forming a damascene structure in the insulating interlayer; and then forming a metal layer over the insulating interlayer and filling the damascene structure; and then forming a metal line by planarizing the metal layer to expose the upper surface of the insulating interlayer; and then forming a plurality of pores in the insulating interlayer by performing thermal treatment after forming the metal line.

Accordingly, in a method of fabricating a semiconductor device in accordance with embodiments, after such a process requiring a prescribed mechanical strength as CMP has been performed, a heat treatment such as annealing is conducted for forming pores in an insulating layer to maximize the mechanical strength of the insulating layer. Therefore, it is advantageous for obtaining high integration by lowering the resistance of the copper (Cu) line. Moreover, a separate annealing process for forming the copper (Cu) is omitted, thereby maximizing the overall performance and reliability of the semiconductor device.

### DRAWINGS

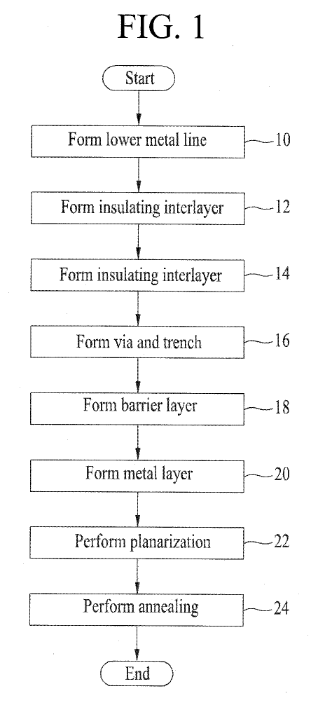

Example FIG. 1 illustrates a flowchart for a method of fabricating a semiconductor device in accordance with embodiments.

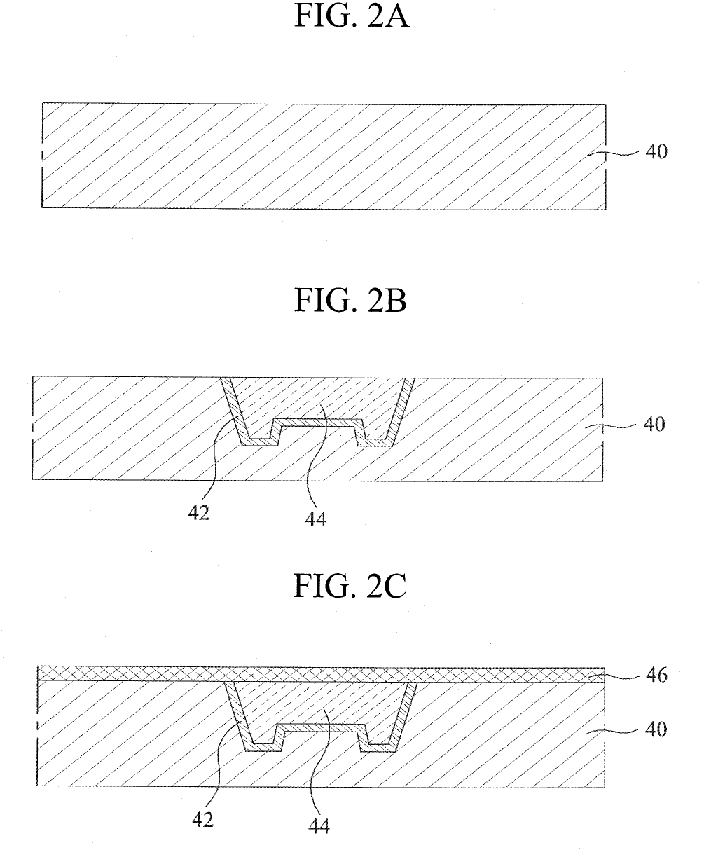

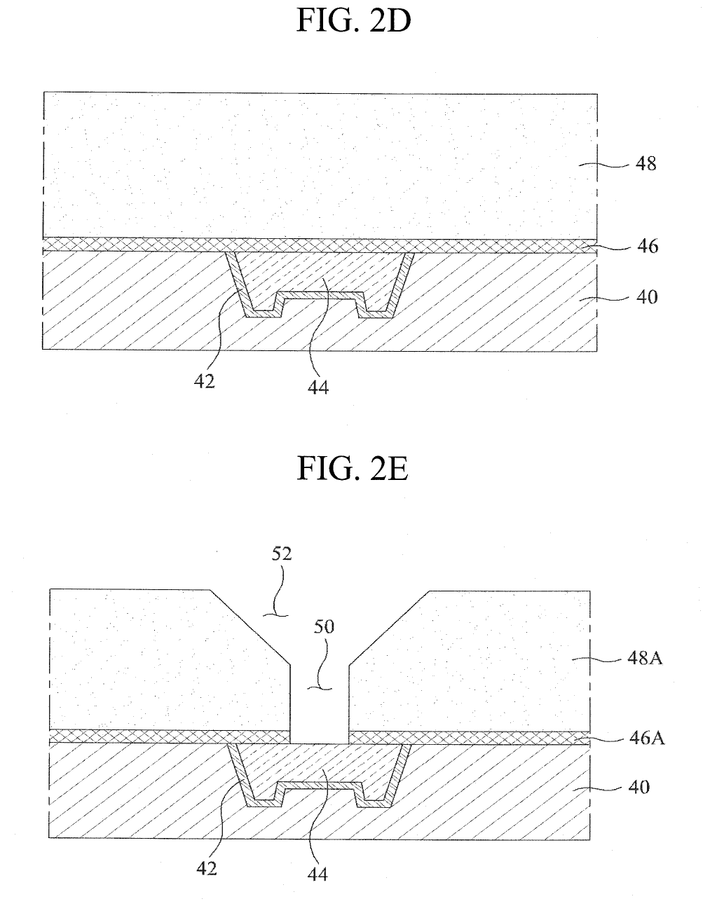

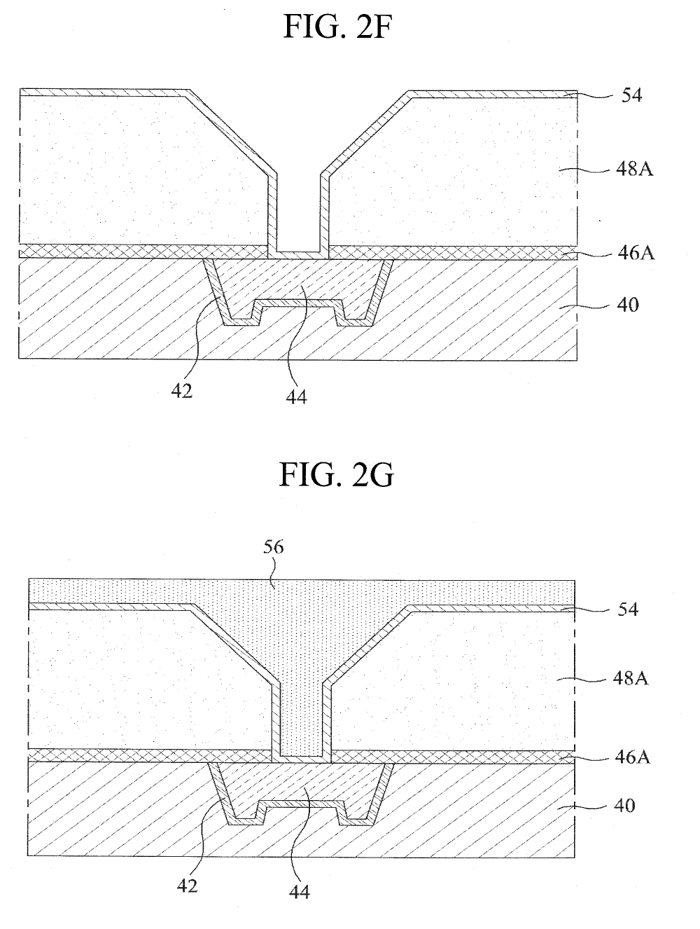

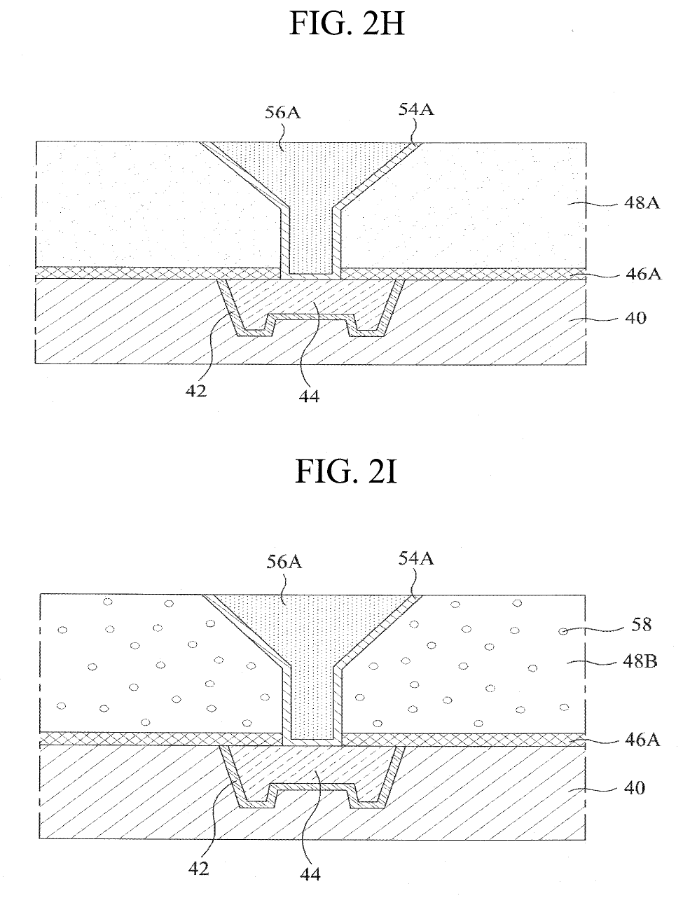

Example FIGS. 2A to 2I illustrate a method of fabricating a semiconductor device in accordance with embodiments.

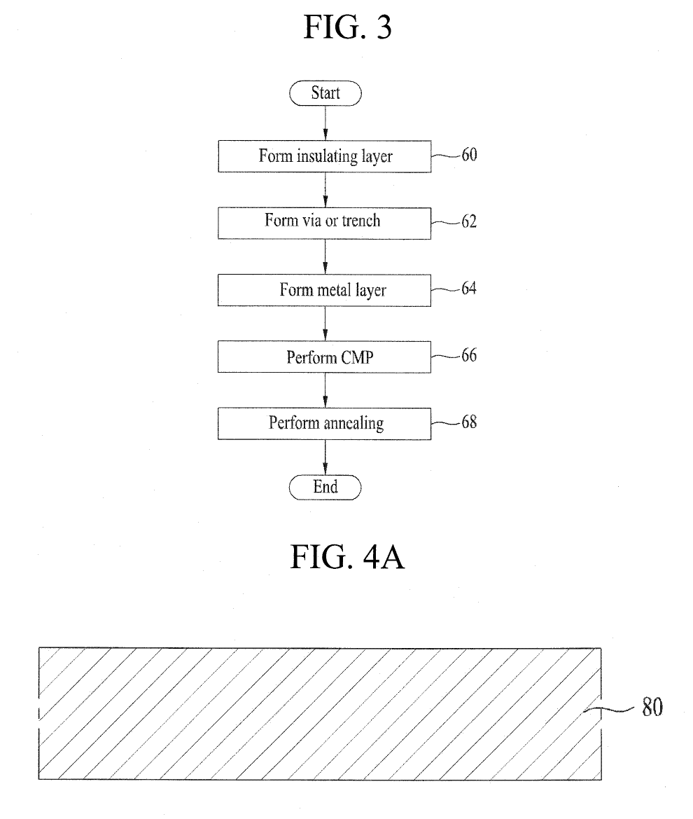

Example FIG. 3 illustrates a flowchart for a method of fabricating a semiconductor device in accordance with embodiments.

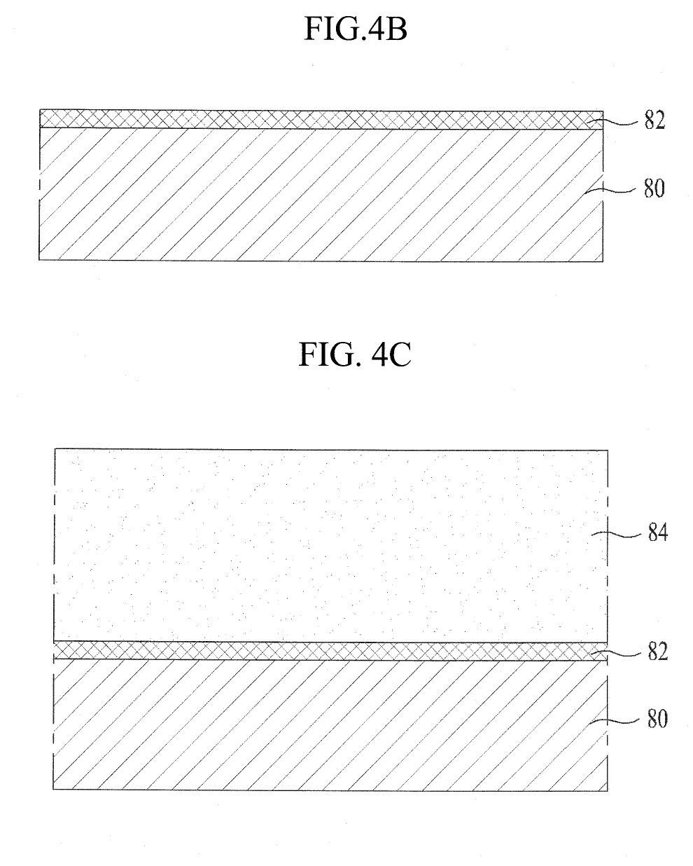

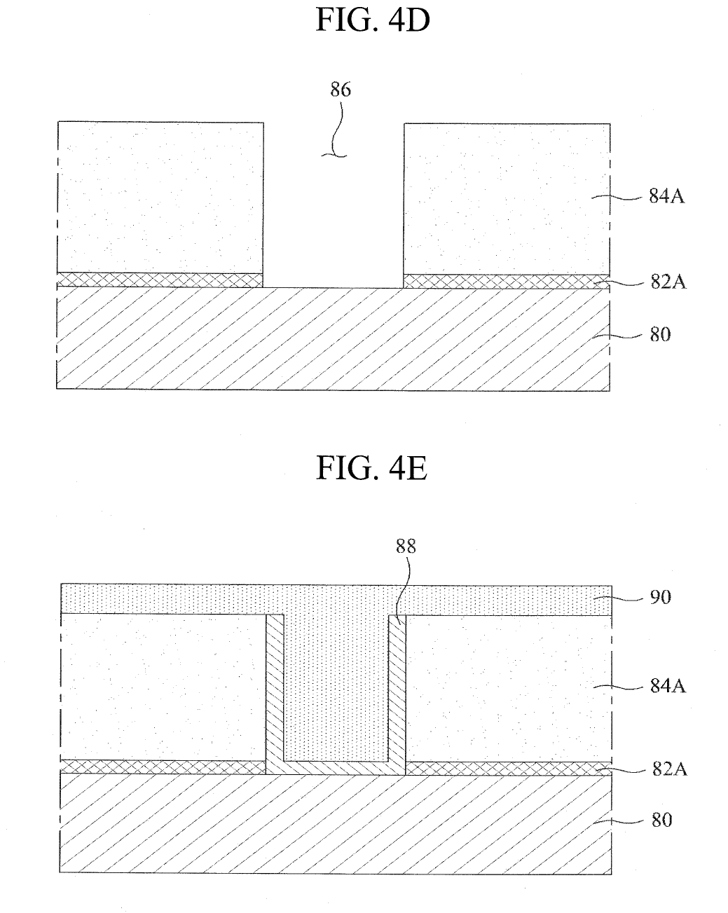

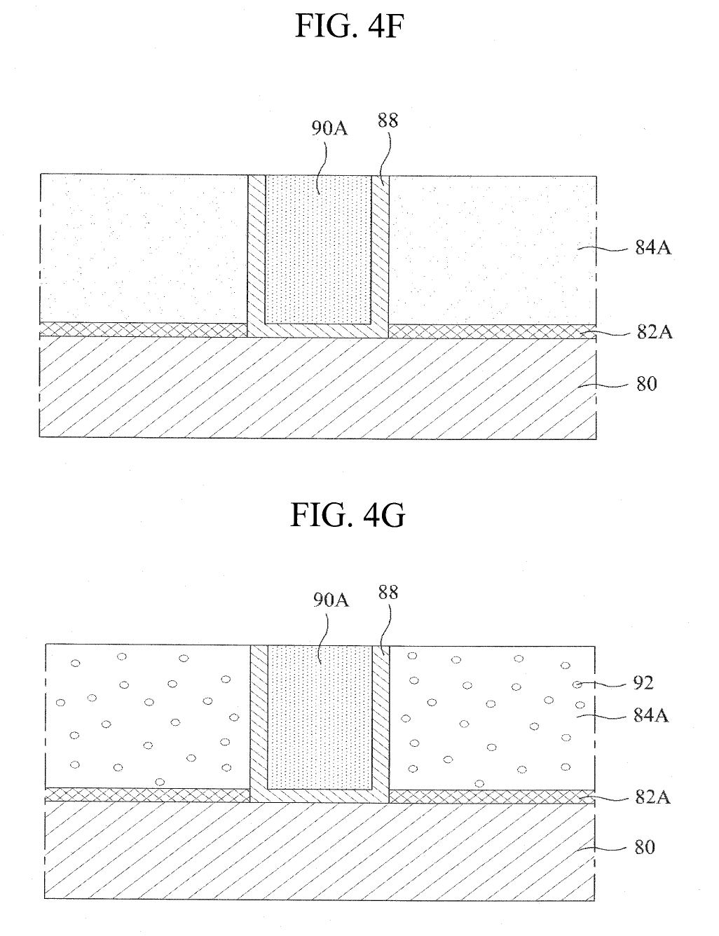

Example FIGS. 4A to 4G illustrate a method of fabricating a semiconductor device in accordance with embodiments.

### DESCRIPTION

Reference will now be made in detail to embodiments, examples of which are illustrated in the accompanying drawings. Wherever possible, the same reference numbers will be used throughout the drawings to refer to the same or like parts.

As illustrated in example FIGS. 1 and 2A to 2I, a method of fabricating a semiconductor device in accordance with embodiments may have a dual damascene line structure.

As illustrated in example FIG. 2A, for a method of fabricating a semiconductor device in accordance with embodiments may include forming lower insulating layer 40 is formed on and/or over a semiconductor substrate.

As illustrated in example FIGS. 1 and 2B, lower metal line 44 is then formed in lower insulating layer 40 [step S10]. Lower metal line 44 can be formed of copper (Cu). Preferably, barrier layer 42 for preventing diffusion of copper (Cu) into lower insulating layer 40 can be formed between lower metal line 44 and lower insulating layer 40.

As illustrated in example FIG. 2C, after completion of step S10, etch-stop layer 46 is formed on and/or over insulating layer 40 including lower metal line 44 and barrier layer 42 [step S12]. Etch-stop layer 46 can be formed of a nitride layer. Configurations of lower metal line 44 and barrier layer 42 are just exemplary and do not limit various embodiments.

As illustrated in example FIG. 2D, after completion of step S12, one of an insulating layer and insulating interlayer (inter-metallic dielectric layer) 48 is formed on and/or over etch-stop layer 46 [step S14]. If etch-stop layer 46 is not provided, insulating interlayer 48 is formed on and/or over exposed surfaces of lower metal line 44, lower insulating layer 40 and barrier layer 42 [step S14]. Insulating interlayer 48 can be formed of one of polymer, spin-on-glass (SOG) by coating or the like. Alternatively, insulating interlayer 48 can be formed by chemical vapor deposition (CVD).

As illustrated in example FIG. 2E, after completion of step S14, via-hole 50 and trench 52 are formed by patterning insulating interlayer 48 by a process such as photolithography [step S16]. In particular, via-hole 50 is initially formed by conducting a first etching process patterning of insulating interlayer 48 by photolithography. The etch process for forming via-hole 50 is performed until etch-stop layer 46 is exposed. After via-hole 50 has been formed, trench 52 is formed on and/or over via-hole 50 by a second etching process such as photolithography. In the course of forming trench 52, a portion of etch-stop layer 46 is etched to expose metal line 44 under via-hole 50.

As illustrated in example FIG. 2F, after completion of step S16, second barrier layer 54 is deposited on and/or over an upper surface of exposed lower metal line 44 through etch-stop layer 46A and an exposed surface of insulating interlayer 48A [step S18]. Second barrier layer 54 plays a role in preventing diffusion of copper (Cu) of a subsequently formed metal layer 56 into insulating interlayer 48A. Alternatively, unlike example FIG. 2F, second barrier layer 54 can be formed only on and/or over inner sidewalls of via-hole 50 and trench 52 and not on and/or over the upper surface of insulating interlayer 48A.

As illustrated in example FIG. 2G, after completion of step S 18, metal layer 56 is formed on and/or over insulating interlayer 48A including barrier layer 54 and filling via-hole 50 and trench 52 [step S20]. Metal layer 56 can be formed of copper (Cu). Metal layer 56 can be formed using one of physical vapor deposition (PVD), chemical vapor deposition (CVD) and electro-chemical plating (ECP). If metal layer 56 is formed by ECP, via-hole 50 and trench 52 can be filled up with copper (Cu) in a manner of depositing a seed copper (Cu) layer on and/or over barrier layer 54 by PVD or CVD and then forming metal layer 56 as a copper (Cu) layer by dipping the resultant structure in an electrolyte. Moreover, metal layer 56 can be formed as a copper (Cu) bulk to cover an upper surface of insulating interlayer 48A including barrier layer 54 as well as gap-fill via-hole 50 and trench 52.

As illustrated in example FIG. 2H, after completion of step S20, metal layer 56 is planarized by CMP until an upper surface of insulating interlayer 48A is exposed [step S22]. The planarized metal layer 56A becomes an upper metal line.

As illustrated in example FIG. 2I, after completion of step S22, a plurality of pores 58 are formed in insulating interlayer 48A by performing a thermal treatment process such as annealing on and/or over the resultant planarized result structure [step S24]. As organic substance is removed from insulating interlayer 48A by the annealing process of step S24, pores 58 are formed. A dielectric constant of insulating interlayer 48A having pores 58 is thereby decreased. Moreover, the thermal treatment of step S24 plays a role as general annealing which is performed after completion of the gap-fill of via-hole 50 and trench 52 with copper (Cu). Therefore, porous insulating layer 48B is formed.

As illustrated in example FIGS. 3 and 4A to 4G, a method of fabricating a semiconductor device in accordance with embodiments may have a single damascene line structure.

As illustrated in example FIGS. 4A and 4B, etch-stop layer 82 is formed on and/or over semiconductor substrate 80. Etch-stop layer 82 can be formed as a nitride layer.

As illustrated in example FIG. 4C, insulating layer 84 can then be formed on etch-stop layer 82 [step S60]. Etch-stop layer 82 and insulating layer 84 correspond to etch-stop layer 46 and insulating interlayer 48 illustrated in example FIG. 2D, which are formed of the same materials to play the same roles, respectively.

As illustrated in example FIG. 4D, after completion of step S60, one of via-hole and trench 86 exposing semiconductor substrate 80 is formed by patterning insulating layer 84 by photolithography [step S62]. A process for forming via-hole or trench 86 may be the same as the process for forming via-hole 50 illustrated in example FIG. 2E.

As illustrated in example FIG. 4E, after completion of step S62, metal layer 90 is formed on and/or over insulating layer 84A and filling via-hole or trench 86 [step S64]. Metal layer 90 can be formed by the same method for forming metal layer 56 illustrated in example FIG. 2G. In accordance with embodiments, barrier layer 88 can be formed to prevent diffusion of copper (Cu) of subsequent-formed metal layer 90 into insulating layer 84A. Barrier layer 88 can be formed on and/or over inner sidewalls of via-hole or trench 86 or may be formed on an upper surface of insulating layer 84A as well as the inner sidewalls of via-hole or trench 86.

As illustrated in example FIG. 4F, after completion of step S64, metal layer 90is planarized by CMP until the upper surface of insulating layer 84A is exposed [step S66].

As illustrated in example FIG. 4G, after completion of step S66, a plurality of pores 92 are formed in insulating layer 84A by performing a thermally treatment or annealing of the resultant planarized structure [step S68]. Therefore, by forming pores 92 in a manner of removing organic substance contained in insulating interlayer 84B through the thermal treatment, a porous insulating layer 84B is formed. As the organic substance contained in insulating interlayer 84A is removed by the thermal treatment of step S68, pores 92 are formed. Hence, a dielectric constant of he insulating interlayer 84B having pores 92 becomes further reduced. Besides, the thermal treatment process of step S68 plays a role as general annealing performed after gap-filling via-hole or trench 86 with copper (Cu).

In accordance with embodiments, in step S24 or S68, the thermal treatment process can be performed at a temperature in a range between approximately 300 to 450° C. for a time limit in a range between approximately 30 to 60 minutes using one of nitrogen gas (N₂) and hydrogen (H₂) gas to prevent chemical changes to the structure of the insulating layer. Preferably, in order to form pores in the insulating layer through thermal treatment, the insulating interlayer may have a methyl functional group (CₓH_{y}). This is because the methyl group evaporates at the high temperature of the thermal treatment (outgasing). Since the methyl group is normally removed at a temperature in a range between approximately 350 to 450° C., each of the pores can be formed at the vacancy having been occupied by the methyl group. In order to enable the k value of the insulating layer to have a value equal to or less than 3.0, the pores should occupy at least 30% of the volume of the insulating layer. For this, the thermal treatment process can be optimally performed.

In case of a semiconductor device fabricating method, annealing for lowering the dielectric constant of the insulating layer is performed prior to the planarization process. However, in the semiconductor substrate fabricating method in accordance with embodiments, an annealing process is performed after completion of the planarization process. Accordingly, the semiconductor device fabricating method in accordance with embodiments maximizes the mechanical strength for planarization that is performed in a state free from pores.

In case of a semiconductor device fabricating method, annealing for Cu should be performed after deposition of the Cu metal layer in addition to the annealing for forming pores in the insulating layer. However, in accordance with embodiments, the annealing process of steps S24 and S68 are performed after completion of the planarization step S22 or S66 also serves to anneal the Cu. Therefore, a separate annealing for Cu is not required.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method of fabricating a semiconductor device comprising:
forming an insulating interlayer over a semiconductor substrate; and then
forming a via-hole and a trench by patterning the insulating interlayer; and then
forming a metal layer over the insulating interlayer and filling the via-hole and the trench; and then
forming a metal line by planarizing the metal layer until an upper surface of the insulating interlayer is exposed; and then
forming pores in the insulating interlayer by performing thermal treatment after forming the metal line.

2. The method of claim 1, further comprising, after forming the via-hole and the trench and before forming the metal layer, forming a barrier layer over the surface of the insulating interlayer and over sidewalls of the via-hole and the trench.

3. The method of claim 2, wherein the metal layer is formed over and contacts the barrier layer.

4. The method of claim 1, further comprising, after forming the via-hole and the trench and before forming the metal layer, forming a barrier layer over sidewalls of the via-hole and the trench.

5. The method of claim 4, wherein the metal layer is formed over and contacts the upper surface of the insulating layer.

6. The method of claim 1, wherein forming the metal layer comprises: forming a copper layer over the insulating interlayer and filling the via-hole and the trench.

7. The method of claim 6, wherein the copper layer is formed by one of physical vapor deposition, chemical vapor deposition and electro-chemical plating.

8. The method of claim 1, further comprising, before forming the insulating interlayer:
forming a lower insulating interlayer over the semiconductor substrate; and then
forming a lower metal line in the lower insulating layer, wherein the insulating interlayer is formed over the lower metal line and the lower insulating layer and the lower metal layer corresponds to the metal line.

9. The method of claim 8, further comprising, after forming the lower metal line and before forming the insulating interlayer: forming an etch-stop layer over the lower metal line and the lower insulating layer, wherein the insulating interlayer is formed on the etch-stop layer.

10. The method of claim 9, wherein forming the via-hole and trench comprises:
forming the via-hole by etching the insulating interlayer until the etch-stop layer is exposed; and then
forming the trench over the via-hole by etching the insulating interlayer and the exposed etch-stop layer to thereby expose the lower metal line.

11. The method of claim 1, wherein the thermal treatment is performed at a temperature in a range between approximately 300 to 450° C.

12. The method of claim 1, wherein the thermal treatment is performed using one of nitrogen gas and hydrogen gas.

13. The method of claim 1, wherein the insulating interlayer is formed having a methyl functional group.

14. A method comprising:
forming an insulating interlayer over a semiconductor substrate; and then
forming a damascene structure in the insulating interlayer; and then
forming a metal layer over the insulating interlayer and filling the damascene structure; and then
forming a metal line by planarizing the metal layer to expose the upper surface of the insulating interlayer; and then
forming a plurality of pores in the insulating interlayer by performing thermal treatment after forming the metal line.

15. The method of claim 14, wherein the damascene structure comprises one of a single damascene structure and a dual damascene structure.

16. The method of claim 14, further comprising, after forming the damascene structure and before forming the metal layer: forming a barrier layer over the surface of the insulating interlayer and over sidewalls of the damascene structure, wherein the metal layer is formed over and contacts the barrier layer.

17. The method of claim 14, further comprising, after forming the damascene structure and before forming the metal layer, forming a barrier layer over sidewalls of the damascene structure, wherein the metal layer is formed over and contacts the upper surface of the insulating layer.

18. The method of claim 14, wherein the thermal treatment is performed at a temperature in a range between approximately 300 to 450° C.

19. The method of claim 14, wherein the thermal treatment is performed using one of nitrogen gas and hydrogen gas.

20. The method of claim 12, wherein the insulating interlayer is formed having a methyl functional group.
